(19) United States
(12) Patent Application Publication
(10) Pub. No.: US 2025/0374423 A1
(43) Pub. Date: Dec. 4, 2025

(54) ELECTRONIC DEVICE CARRIER STRUCTURES INCLUDING POLYMER LAYERS AS BARRIERS TO SOLID STATE SOLDER DIFFUSION AND METHODS OF FORMING THE SAME

(71) Applicants: Georgia Tech Research Corporation, Atlanta, GA (US); Intel Corporation, Santa Clara, CA (US)

(72) Inventors: Omkar Gupte, Atlanta, GA (US); Vanessa Smet, Atlanta, GA (US); Gregorio R. Murtagian, Phoenix, AZ (US)

(21) Appl. No.: 18/987,268

(22) Filed: Dec. 19, 2024

Related U.S. Application Data
(63) Continuation of application No. 17/664,408, filed on May 21, 2022, now Pat. No. 12,207,398.
(60) Provisional application No. 63/194,633, filed on May 28, 2021.

(51) Int. Cl. H05K 1/02; H05K 1/09; H05K 3/22

(52) U.S. Cl. CPC H05K 1/0296; H05K 1/09; H05K 3/22; H05K 2201/10734

(57) ABSTRACT

An electronic device carrier structure can include a substrate including a plurality of electrical contacts spaced apart on the substrate, a plurality of electrically conductive balls, each of the electrically conductive balls being on a respective one of the plurality of electrical contacts, solder attaching each of the electrically conductive balls to respective ones of the electrical contacts to form an attachment boundary where the solder ends on a surface of each of the plurality of electrically conductive balls, and a polymer layer extending on the substrate onto the plurality of electrically conductive balls to form a surface of the polymer layer at a contact point on the plurality of electrically conductive balls that is above the attachment boundary and below an apex of each of the plurality of electrically conductive balls.

### CLAIM FOR PRIORITY

This application is a continuation of U.S. Non-provisional application Ser. No. 17/664,408, filed May 21, 2022, entitled ELECTRONIC DEVICE CARRIER STRUCTURES INCLUDING POLYMER LAYERS AS BARRIERS TO SOLID STATE SOLDER DIFFUSION AND METHODS OF FORMING THE SAME, which claims priority to U.S. Provisional Patent Application No. 63/194,633, entitled POLYMER COLLARS AS MECHANICAL DIFFUSION BARRIERS FOR SOLID STATE SOLDER DIFFUSION, filed May 28, 2021, each of which is hereby incorporated herein by reference.

### STATEMENT OF GOVERNMENT SUPPORT

This invention was made with government support under Grant No. HR0011-13-3-0002 awarded by the Department of Defense/Defense Advanced Research Projects Agency (DARPA). The government has certain rights in the invention.

### FIELD

The present invention relates to the field electronics in general, and more particularly, to interconnect for electronic devices.

### BACKGROUND

Microprocessors (and similar devices) have traditionally been packaged using Land Grid Array (LGA) designs and have been press-fitted into sockets. However, Ball Grid Array (BGA) designs, used in surface mount (SMT) applications, have concurrently gained popularity primarily due to their smaller form factor and improved electrical performance owing to the reduced interconnection length. BGA packages, when used directly in sockets, may face several challenges, such as damage to the soft solder spheres under the socket latching force, surface oxidation of the spheres, and intermetallic (IMC) formation between the solder spheres and the socket paddles, which may increase the contact resistance and degrade reworkability.

To address these challenges, different compliant contact technologies, such as tweezer contact, Dendriplate, and four-point crown, have been developed that minimize the damage to the solder spheres and expose a fresh layer of solder underneath the native oxide layer.

### SUMMARY

Embodiments according to the present invention can provide electronic device carrier structures including polymer layers as barriers to solid state solder diffusion and methods of forming the same. Pursuant to these embodiments, an electronic device carrier structure can include a substrate including a plurality of electrical contacts spaced apart on the substrate, a plurality of electrically conductive balls, each of the electrically conductive balls being on a respective one of the plurality of electrical contacts, solder attaching each of the electrically conductive balls to respective ones of the electrical contacts to form an attachment boundary where the solder ends on a surface of each of the plurality of electrically conductive balls, and a polymer layer extending on the substrate onto the plurality of electrically conductive balls to form a surface of the polymer layer at a contact point on the plurality of electrically conductive balls that is above the attachment boundary and below an apex of each of the plurality of electrically conductive balls.

### BRIEF DESCRIPTION OF THE DRAWINGS

FIG. 1 is a schematic illustration of an electronic device carrier including a substrate, positioned over a device, the substrate including electrically conductive balls attached to electrical contacts on the substrate by solder that is encapsulated by a polymer layer that extends on the substrate to contact the electrically conductive balls in some embodiments according to the invention.

FIG. 2A is a schematic illustration of the polymer layer extending on the substrate to form polymer fillets at contact points on the surfaces of the electrically conductive balls above where the solder attaches the electrically conductive balls to the electrical contacts on the substrate in some embodiments according to the invention.

FIG. 2B is a schematic illustration of an electrically conductive ball on the substrate and an attachment boundary, where the solder that attaches the electrically conductive ball to the electrical contact, ends in some embodiments according to the invention.

FIG. 2C is a schematic illustration of the region C in FIG. 2A including layers on the electrically conductive ball that provide the surface of the electrically conductive ball contacted by a surface of the polymer layer at a contact point above the attachment boundary and below an apex of the electrically conductive ball in some embodiments according to the invention.

FIG. 3 is a flow chart illustrating the formation of polymer collars by spin-coating a polymer material on a BGA package (as the substrate) to form the polymer layer having the polymer fillets covering the attachment boundaries of the solder in some embodiments according to the invention.

FIG. 4 is a graph of the ratio of the height of the electrically conductive balls to the height of the polymer collar plotted against the spin coating RPM in some embodiments according to the invention.

FIG. 5 is an image illustrating adjacent electrically conductive (solder) balls formed according to embodiments of the present invention.

FIGS. 6(a)-(j) show XPS data for a test structure evaluated at 100 degrees Centigrade with devices formed with the polymer collars compared to devices formed without the polymer collars according to embodiments of the invention.

FIGS. 7(a)-(j) show XPS data for a test structure evaluated at 120 degrees Centigrade with devices formed with the polymer collars compared to devices formed without the polymer collars according to embodiments of the invention.

### p DETAILED DESCRIPTION OF EMBODIMENTS ACCORDING TO THE INVENTION

Exemplary embodiments of the present disclosure are described in detail with reference to the accompanying drawings. The disclosure may, however, be exemplified in many different forms and should not be construed as being limited to the specific exemplary embodiments set forth herein. Rather, these exemplary embodiments are provided so that this disclosure will be thorough and complete, and will fully convey the scope of the disclosure to those skilled in the art.

As appreciated by the present inventors, Ball Grid Array (BGA) package designs are increasingly used in surface mount applications while Land Grid Array (LGA) designs are predominantly used in socketing. BGA spheres with a noble metal surface may provide a stable mechanical contact interface with the socket paddles. These noble contact interfaces, however, should remain intact throughout the socketing life of the product.

As disclosed herein, in some embodiments according to the invention, polymer collars can be formed on electrically conductive balls (such as solder balls) to prevent solid-state wicking of constituent material in the solder along the surface of the ball, which may otherwise affect the electrical conductivity of the ball. As described herein, in some embodiments according to the invention, the polymer collars may be formed by spin-coating a polymer material on the surface of a substrate that can have the conductive balls mounted thereon.

Experiments were performed on samples that included polymer collar. For example, polymer material was spin coated onto a substrate to form polymer collars according to embodiments of the present invention, on Au coated solder balls adhered to the substrate. The substrate was then aged alongside a reference package with no polymer collars, at accelerated test temperatures of 100° C. and 120° C., respectively. After 650 hours of aging, XPS studies showed no Au signal but a strong Sn signal in the reference package (without the polymer collars), which evidenced solder wicking from the solder ball-attach joints to an upper portion of the solder ball, whereas the Au signal was detected for the package with the polymer collars, evidencing that the polymer collars did inhibiting solid-state solder wicking from the ball-attach joints. The joints with polymer collars also showed mechanical stability throughout thermal aging with a 3× improvement in joint shear strength.

In still further experiments on devices formed according to embodiments of the present invention, the surfaces of the solder balls in a BGA interconnect were covered with multi-layered metallic coatings configured to be compatible with socketing and SMT applications. The coating included a diffusion barrier/noble metal combination with thicknesses configured to control interfacial reactions. The coating was directly applied on the spheres prior to their attach onto the BGA packages with solder paste. In some embodiments according to the present invention, a Ni—Au coating may be used to provide a diffusion barrier. In a socketing system configured for use with embodiments according to the present invention, the Au may provide a stable mechanical contact interface between the coated balls and the socket paddles and the Ni may prevent the diffusion of Sn from the solder core to the outer surface of the balls.

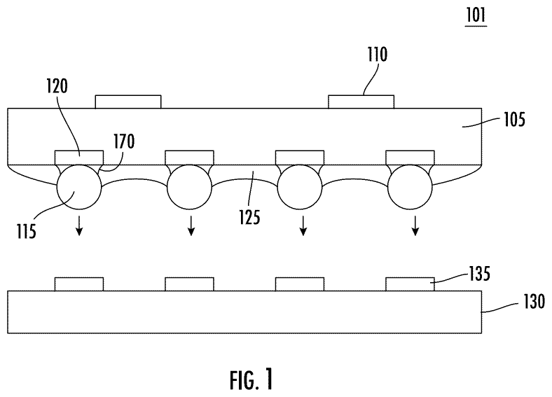

FIG. 1 is a schematic illustration of an electronic device carrier 101 including a substrate 105, positioned over a device 130, the substrate 105 including electrically conductive balls 115 attached to electrical contacts 120 on the substrate 105 by solder 170 that is encapsulated by a polymer layer 125 that extends on the substrate 105 to contact the electrically conductive balls 115 in some embodiments according to the invention. According to FIG. 1, in some embodiments according to the invention, the device 130 can be part of a circuit board or other structure that carries electrical devices where the electronic device carrier 101 is subjected to a solder reflow process to couple the device carrier 101 to the circuit board or other structure. Accordingly, in such embodiments according to the invention, the electronic device carrier 101 can be configured as what is sometimes referred to as a Ball Grid Array. The electronic device carrier 101 can carry one or more electronic devices 110, which can be electrically connected to the electrical contacts 120.

As appreciated by the present inventors, the electrically conductive balls 115 can be attached to the electrical contacts 120 by a paste, such as solder paste, that includes constituent elements that may (if not addressed) diffuse along the surface of the electrically conductive balls 115 to reach a portion which is configured to contact the electrical contacts 130. Accordingly, in some embodiments according to the invention, the polymer layer 125 can be formed to cover an attachment boundary 165 on the surface of the electrically conductive balls 115 where the solder attaches to the electrically conductive balls 115. The polymer layer 125 can provide a barrier against the diffusion of the elements included in the solder on the surface of the electrically conductive balls 115.

In some embodiments according to the invention, the device 130 can be part of a socket that allows the electronic device carrier 101 to be removably coupled to socket. Accordingly, in some embodiments according to the invention, the electronic device carrier 101 can be configured as what is sometimes referred to as a Land Grid Array. The device 130 can include contacts 135 thereon that are configured to be coupled to respective ones of the electrically conductive balls 115.

It will be understood that, in some embodiments according to the invention, the electrically conductive balls 115 can be solder. In some embodiments according to the invention, the electrically conductive balls 115 can be copper. Other materials can also be used. It will be understood that in some embodiments according to the invention, the term “electrically conductive balls” can include any material that is sufficient for electrical connectivity between electrical components. It will be understood that in some embodiments according to the invention, the term “electrically conductive” includes materials that provide a specific resistivity of less than about 10⁻³ ohm-cm² and, in some embodiments less than about 10⁻⁴ ohm-cm² to about 10⁻⁶ ohm-cm².

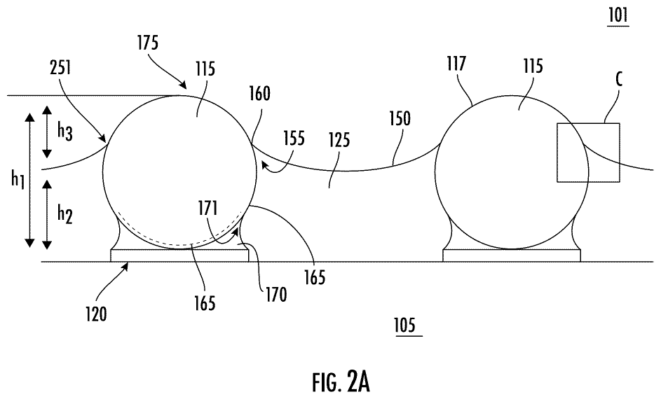

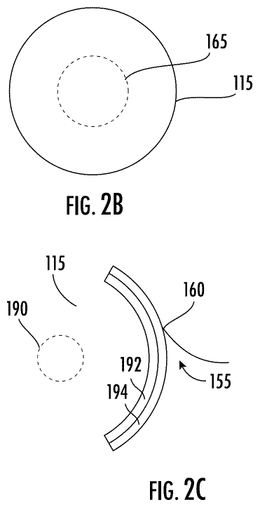

FIG. 2A is a schematic illustration of the polymer layer 125 extending on the substrate 105 to form polymer fillets 155 at contact points 160 on the surfaces 117 of the electrically conductive balls 115 above where the solder 170 attaches the electrically conductive balls 115 to the electrical contacts 120 in some embodiments according to the invention. As further shown in FIG. 2A, the upper surface 150 of the polymer layer 125 extends over the substrate 105 to contact the surfaces 117 of the electrically conductive balls 115 at respective contact points 160. The contour of the upper surface 150 of the polymer layer 125 curves upward proximate to the surface 117 to form a polymer fillet 155 at the surface 117 as shown.

The solder 170 attaches the electrically conductive balls 115 to the contacts 120 to form an attachment boundary 165 where the solder ends on the surface 117. The contact point 160 is high enough on the surface 117 to cover the attachment boundary 165 to prevent the diffusion of the constituent elements of the solder over time. In some embodiments according to the invention, the maximum height of the electrically conductive balls 115 about the surface of the substrate 105 is h1, whereas the maximum height of the attachment boundary 165 above the substrate 105 is h2. As described herein, the viscosity of the polymer material can be selected based on the ration of h1/h2 so that the height of the polymer layer 125 is formed to be above the attachment boundary 165 but below the apex 175 of the electrically conductive balls 115. In some embodiments according to the invention, the height of the polymer layer 125 is at about the mid-point 251 between the attachment boundary 165 and the apex 175.

FIG. 2B is a plan view of the electrically conductive ball 115 on the substrate 105 in FIG. 2A and the attachment boundary 165, where the solder that attaches the electrically conductive ball 115 to the electrical contact 12 ends in some embodiments according to the invention.

FIG. 2C is a enlarge illustration of the region C in FIG. 2A including multiple layers formed on the electrically conductive ball 115 to provide the surface 117 of the electrically conductive ball 117 contacted by the upper surface 150 of the polymer layer 125 at the contact point 160 above the attachment boundary 165 and below the apex 175 of the electrically conductive ball in some embodiments according to the invention. As shown in FIG. 2C, the multiple layers can include layer an inner layer 192 and an outer layer 194. In some embodiments according to the invention, the outer layer 194 can be noble metal. In some embodiments according to the invention, the inner and outer layers 192, 194 can be metals. Additional layers may also be formed. In some embodiments according to the invention, the electrically conductive ball 115 can include a polymer core 190.

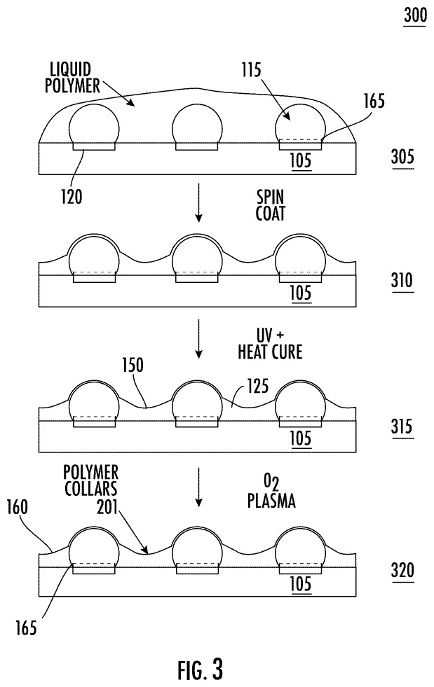

FIG. 3 is a flowchart 300 illustrating the formation of polymer collars 201 by spin-coating a polymer material on a BGA package (as the substrate 105) to form the polymer layer 125 having the polymer fillets 155 covering the attachment boundaries 165 on the electrically conductive balls 115 in some embodiments according to the invention. According to FIG. 3, the electrically conductive balls 115 can be initially attached to the electrical contacts 120 by, for example, a solder paste. The solder paste is configured to hold the electrically conductive balls 115 to the electrical contacts 120 during, for example, a solder reflow process where the solder paste liquifies and forms an attachment boundary 165 on the surface of the electrically conductive balls 115 indicating where the reflowed solder ends. Accordingly, the constituent elements of the solder paste may remain in the reflowed solder after the reflow process is complete. As appreciated by the present inventors, however, the polymer collars 201 described herein can be formed on the surface of the electrically conductive balls 115 beyond the attachment boundary 165 to cover the location of the reflowed solder. Accordingly, the diffusion of the elements of the solder paste still contained within the reflowed-solder may be prevented so that the adverse effects on the electrically conductive balls 115 may be reduced.

Still referring to FIG. 3, the polymer material is applied to the surface of the substrate (Block 305). The polymer collars 201 can be formed by spin-coating the polymer material, such as a thermoset material, on the substrate 105 to distribute the polymer material between adjacent electrically conductive balls 115 and to form the polymer fillets 155 where the surface of the polymer layer 125 contacts the electrically conductive balls. The polymer fillets can be above (and thereby cover) the attachment boundary 165 to reduce the diffusion of constituent materials include in the material used to attach the electrically conductive balls to the electrical contacts 120 (such as SBA in solder). In some embodiments according to the invention, the polymer material applied to the substrate 105 can be MasterBond® UV-15. The polymer collars 201 may also provide increased joint shear strength.

The spin-coated polymer layer 125 can be cured using 365 nm UV light, followed by heating at 120° C. for 30 min (Block 315). The spin coating may also cause a thin layer of polymer to be deposited on the top surface of the electrically conductive balls 115. This surface contamination may be removed by subjecting the package to 1.5 min of O2 plasma at 250 W power in some embodiments according to the invention (Block 320).

In some embodiments according to the present invention, the polymer layer 125 includes a polymer material having a glass transition temperature that is at least 20 degrees Centigrade greater than the operating temperature range of the electronic devices that are carried by the electronic devices 110. In some embodiments according to the present invention, the polymer layer includes a polymer material having a glass transition temperature that is at least equal to a melting temperature of the solder 170. In some embodiments according to the present invention, the polymer layer includes a polymer material having a glass transition temperature in a range between about 120 degrees Centigrade and about 140 degrees Centigrade. In some embodiments according to the present invention, the polymer layer includes a polymer material having a glass transition temperature in a range between about 160 degrees Centigrade and about 170 degrees Centigrade. In some embodiments according to the present invention, the glass transition temperature of the polymer material used to form the polymer layer 125 is at least 138 degrees Centigrade.

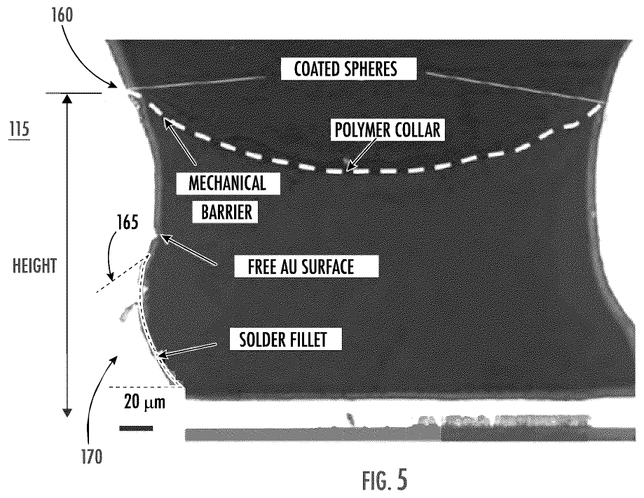

FIG. 5 is an image illustrating adjacent electrically conductive (solder) balls 115 formed according to embodiments of the present invention. The solder balls were formed to a 250 μm diameter and were covered with a multi-layered coating including a 3 μm Ni layer and a 200 nm Au layer. The multi-layered coating was formed by initially sputtering a Ni seed layer, followed by electroless Ni immersion Au (ENIG) coating. A 5 mm×5 mm organic BGA package was formed with 1.5 μm-thick FR-4 cores arranged in a 10 ×10 area array at a 500 μm pitch on the BGA package. A low-temperature SBA paste was printed on the ENIG-coated Cu pads using a stencil, followed by placing the coated solder spheres onto the BGA package and reflowing with a time above liquidus (TAL) of 90 s to obtain the solder joint fillet 171 shown at a height that was less than half the height of the solder ball. The surfaces of the solder balls 115 above the polymer collars (i.e., above the surface 150 of the polymer layer 125) were substantially free of contamination of the constituent elements of the solder paste.

In some embodiments according to the invention, the height of the polymer collars (such as the contact point 160 where the surface of the polymer layer 150 contacts the surface of the electrically conductive balls 115) can be configured so as to completely cover the solder joint (i.e., the attachment boundary). In other words, the height of the surface of the polymer layer 150 which comes into contact with the surface of the electrically conductive balls 115 above the attachment boundary but below the apex 175 of the solder balls can be configured by selecting the spin coating parameters, such as spinning speed and time.

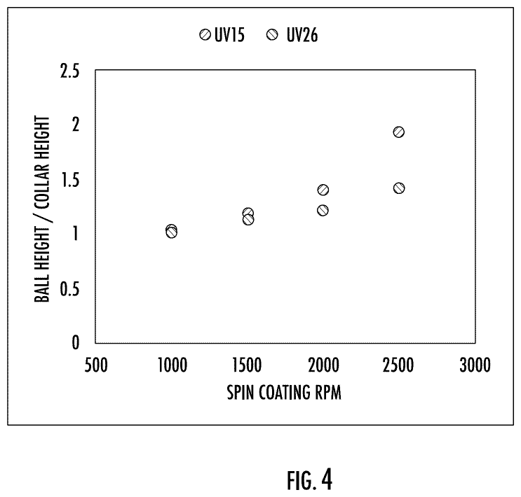

The dependence of the polymer collar height on the spin coating speed is highlighted in FIG. 4 in some embodiments according to the invention. The collar height was measured from the surface of the substrate 105 to the point where the polymer collars 201 contacted the electrically conductive balls 115. Due to the nature of the spin-coating process, the height of the polymer collars is dependent on the height of the electrically conductive balls 115 themselves, which can vary from sample to sample. The ratio of the height of the electrically conductive balls 115 to the height of the polymer collar is plotted against the spin coating RPM in FIG. 4 to normalize the effect of varying ball heights in different packages. As shown in FIG. 4, at higher RPMs the ratio of the height of the electrically conductive balls 115 to the height of the polymer collar increases, which means that the absolute collar height is reduced. Based on this result, the spin coating was done for 30 seconds at 2000 RPM to form exemplary polymer collars 201 according to some embodiments of the present invention. FIG. 5 shows an image of an exemplary substrate 105 with polymer collars 201 formed as described above in some embodiments.

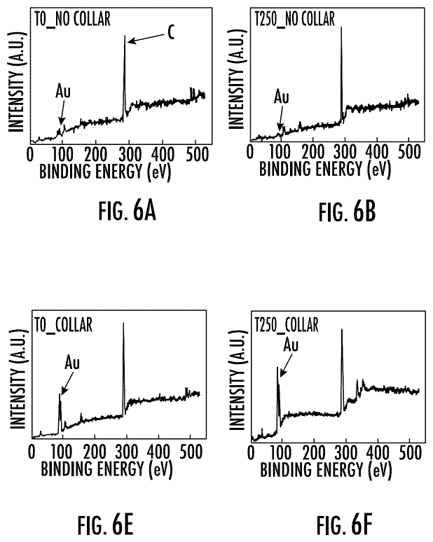

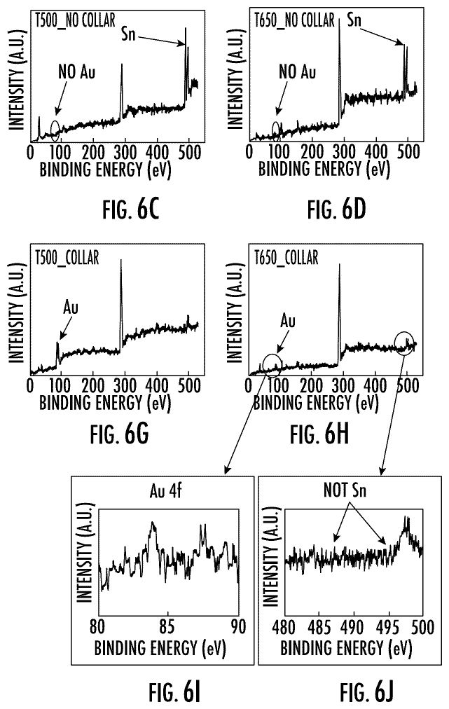

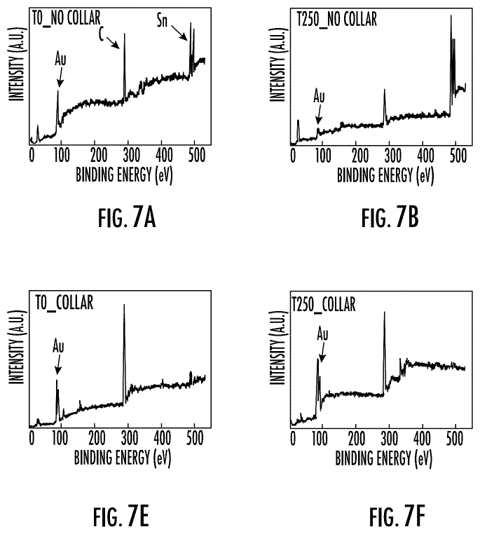

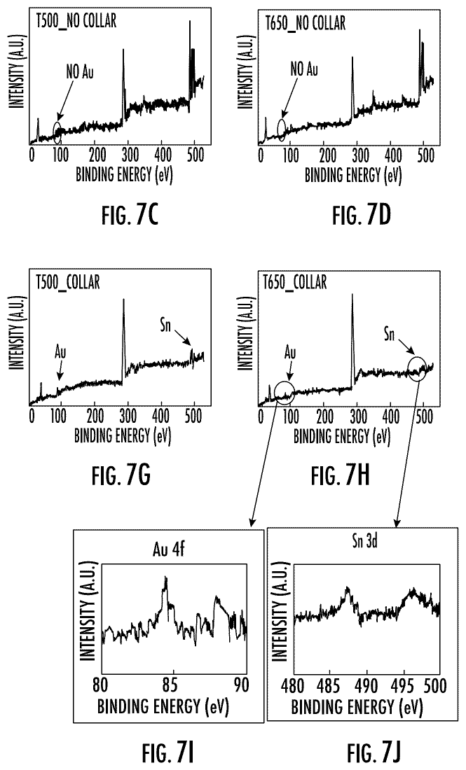

As a comparison, two test structures were formed: one test structure was formed with the polymer collars according to embodiments of the invention and one test structure was formed without polymer collars. Each test structure was aged at temperatures of 100° C. and 120° C., respectively. The composition of the top surface of the thermally aged BGAs was monitored by XPS, with a 50 μm spot size, as fabricated and at aging times of 250 h, 500 h and 650 h. The XPS survey scan images of the top sphere surface for as-fabricated samples with and without polymer collars and after 250 h, 500 h and 650 h of thermal aging at temperatures of 100° C. and 120° C. are shown in FIGS. 6 and 7, respectively.

According to FIGS. 6 and 7, it can be observed that the Au signal intensity reduces with thermal aging at both temperatures, eventually disappearing, for samples without polymer collars. It will be understood that the presence of the peak can be used to determine the presence of the element rather than the intensity of the peak alone. In the case of samples without polymer collars, the presence of Sn on the surface of the spheres was further confirmed by EDX analysis, as due to the curved nature of the analyzed spherical surface and relatively large spot size (50 μm) of the XPS tool used in this study, the detector may catch parasitic amounts of Sn from the area around the sphere, which shows up on the scan. An example of this is seen in FIGS. 6 (a) and FIG. 7 (a) where Sn signal can be seen in the as-fabricated samples. The growing presence of Sn through aging of the as-fabricated samples, as shown in FIG. 6 (a)-(d) and FIG. 7 (a)-(d), indicates continuous solid-state wicking of the solder from the joints to the top surface of the spheres, eventually consuming the entire layer of Au.

In contrast to the above, and as seen in FIGS. 6 (e)-(h), in the sample with polymer collars aged at 100° C., the Au signal is maintained during the entire duration of thermal aging, with a slight reduction in intensity observed at 650 h. FIGS. 6 (i) and 6 (j) shows scans for Au and Sn in the sample illustrated in FIG. 6 (h). As appreciated by the present inventors, the absence of doublet Sn peaks in FIG. 6 (j), evidences that Sn did not diffuse to the top surface after 650 h. This indicates that when the polymer collars cover the attachment boundary of where the solder balls are attached to the solder joints, the constituent components of the solder is captured by the polymer layer, which can provide a barrier to those constituent components of the solder from wicking along the surface toward the apex of the solder balls, where the constituent components of the solder could degrade the conductive nature of the solder balls (if unaddressed).

However, as seen in FIG. 7 (e)-(h) for the sample with polymer collars aged at 120° C., the Au signal intensity starts decreasing after 500 h of thermal aging, as with the sample at 100° C. FIGS. 7 (i) and 7 (j) shows scans for Au and Sn in the sample illustrated in FIG. 7 (h), wherein the presence of minor amounts of Sn is also observed, as shown in FIG. 7 (j). This indicates that, at this temperature, some solid-state diffusion of solder does occur despite the presence of the polymer collars. This can be attributed to the relatively low glass transition temperature (Tg) of the cured polymer collars. The reported Tg of Masterbond® UV-15, when fully cured, is ˜125° C., which is very close to the thermal aging temperature of 120° C. Due to the softness of the polymer, it may provide less barrier to the diffusion, which may lead to the solder components penetrating through the polymer collars and wicking on the sphere surface. Accordingly, in some embodiments according to the present invention, a polymer material with a Tg that is substantially higher than the thermal aging temperature may prevent this phenomenon and successfully capture the constituent components of the solder joints, which otherwise may diffuse. In other embodiments according to the present invention, a solder paste with melting point much higher than the thermal aging temperature may be used to reduce the diffusion rates of the solder, such as standard SAC alloys.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, kit, etc. “consisting of,” i.e., wherein that which is claimed does not include further elements, and a composition, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed:

1. An electronic device carrier structure comprising:
a substrate including a plurality of electrical contacts spaced apart on the substrate;
a plurality of electrically conductive elements, each electrically conductive element positioned on a respective one of the plurality of electrical contacts;
conductive material attaching each electrically conductive element to a respective one of the electrical contacts, wherein the conductive material terminates at an attachment boundary on each conductive element; and
a barrier layer disposed on the substrate and extending onto each of the plurality of electrically conductive elements, wherein the barrier layer at least partially covers each electrically conductive element and extends beyond the attachment boundaries such that a surface of the barrier layer terminates at a contact point on each electrically conductive element.

2. The electronic device carrier structure of claim 1, wherein each electrically conductive element comprises an electrically conductive body having a generally spherical shape.

3. The electronic device carrier structure of claim 1, wherein the conductive material comprises a solder composition.

4. The electronic device carrier structure of claim 1, wherein the barrier layer includes a polymer-based layer.

5. The electronic device carrier structure of claim 1 wherein the each of the plurality of electrically conductive elements is entirely encapsulated by a respective noble metal to form the surface of each of the electrically conductive elements.

6. The electronic device carrier structure of claim 1, wherein each of the plurality of electrically conductive elements comprises a polymer core.

7. The electronic device carrier structure of claim 1, wherein the contact point of the surface of the barrier layer is positioned approximately equidistant between the attachment boundary and an apex of each of the plurality of electrically conductive elements.

8. The electronic device carrier structure of claim 1, wherein the contact point of the surface of the barrier layer is located between the attachment boundary and an apex of each of the plurality of electrically conductive elements.

9. The electronic device carrier structure of claim 1, wherein the barrier layer substantially prevents migration of solder constituents beyond the attachment boundary under thermal stress conditions.

10. The electronic device carrier structure of claim 1, wherein the electrically conductive elements include a multi-layered metallization stack comprising an inner diffusion barrier layer and an outer noble metal layer.

11. The electronic device carrier structure of claim 1 further comprising:
an electronic device on the substrate, the electronic device electrically coupled to the plurality of electrically conductive elements, wherein the electronic device operates in an operating temperature range; and
wherein the barrier layer comprises a polymer material having a glass transition temperature that is greater than the operating temperature range.

12. The electronic device carrier structure of claim 11, wherein the glass transition temperature of the polymer material is at least 20 degrees Centigrade greater than the operating temperature range.

13. The electronic device carrier structure of claim 1, wherein the barrier layer comprises a polymer material having a glass transition temperature that is at least equal to a melting temperature of the conductive material.

14. The electronic device carrier structure of claim 1, wherein the barrier layer comprises a polymer material having a glass transition temperature that is in a range between about 120 degrees Centigrade and about 170 degrees Centigrade.

15. The electronic device carrier structure of claim 1, wherein the barrier layer comprises a polymer material having a viscosity value selected based on a ratio of a maximum height of the electrically conductive elements above a surface of the substrate to a maximum height of the attachment boundary above the surface of the substrate.

16. A method of forming an electronic device carrier structure, the method comprising:
providing a substrate including a plurality of electrical contacts spaced apart on a surface of the substrate, each of the plurality of electrical contacts having conductive material disposed thereon;
positioning a plurality of electrically conductive elements on the conductive material on the plurality of electrical contacts, each electrically conductive element positioned on a respective electrical contact;
attaching the plurality of electrically conductive elements to respective electrical contacts using the conductive material, wherein the conductive material terminates at an attachment boundary on each electrically conductive element;
applying a barrier material on the surface of the substrate and extending onto the plurality of electrically conductive elements; and
forming a barrier layer from the barrier material such that the barrier layer at least partially covers each electrically conductive element, extends beyond the attachment boundaries, and terminates at a contact point on each electrically conductive element.

17. The method of claim 16, further comprising:
providing an electronic device on the substrate, the electronic device electrically coupled to the plurality of electrically conductive elements, wherein the electronic device operates in an operating temperature range; and
selecting the barrier material to comprise a polymer material having a glass transition temperature greater than the operating temperature range.

18. The method of claim 17, wherein the glass transition temperature of the polymer material is at least 20 degrees Centigrade greater than the operating temperature range.

19. The method of claim 16, wherein the barrier material comprises a polymer material having a glass transition temperature that is at least equal to a melting temperature of the conductive material.

20. The method of claim 16, wherein the barrier layer comprises a polymer material having a viscosity value selected based on a ratio of a maximum height of the electrically conductive elements above a surface of the substrate to a maximum height of the attachment boundary above the surface of the substrate.
